(19) United States
(12) Patent Application Publication
(10) Pub. No.: US 2026/0311925 A1
(43) Pub. Date: Oct. 8, 2026

(54) ELECTRONIC DEVICE

(71) Applicant: DENSO CORPORATION, Kariya-city (JP)

(72) Inventor: Kei SANADA, Kariya-city (JP)

(21) Appl. No.: 19/392,520

(22) Filed: Nov. 18, 2025

(30) Foreign Application Priority Data
Dec. 17, 2024 (JP) 2024-221024

(51) Int. Cl. H01F 27/28; H01F 27/24; H05K 1/11; H05K 1/181

(52) U.S. Cl. CPC H01F 27/28; H01F 27/24; H05K 1/111; H05K 1/181; H05K 2201/10015; H05K 2201/1003; H05K 2201/10166

(57) ABSTRACT

An electronic device includes: an insulating board; a conductor disposed on the insulating board; and a coupled inductor having coils magnetically coupled to each other. The coils include end coils located at ends in a predetermined direction, and an intermediate coil located between the end coils. The conductor includes a land exposed from the substrate and joined to the coil, and a non-joined conductor not joined to the coil. An area of the non-joined conductor located directly below one of the coils is smaller at directly below the end coil than at directly below the intermediate coil.

### CROSS REFERENCE TO RELATED APPLICATION

This application is based on Japanese Patent Application No. 2024-221024 filed on Dec. 17, 2024, the disclosure of which is incorporated herein by reference.

### TECHNICAL FIELD

The disclosure in this description relates to an electronic device.

### BACKGROUND

An inductance of a coil is adjustable, in US 2020/0373912 A1 (corresponding to JP 6479280 B), which is incorporated herein by reference as explanations of the technical elements in this specification.

### SUMMARY

According to an aspect of the present disclosure, an electronic device includes: a substrate having an insulating board and a conductor disposed on the insulating board; and a coupled inductor having a core and coils disposed on the core. The coils are arranged in a predetermined direction perpendicular to a thickness direction of the substrate and magnetically coupled to each other. The coils include end coils located at ends in the predetermined direction, and an intermediate coil located between the end coils. Each of the coils has a body portion wound around the core and a terminal portion connected to the body portion. The conductor includes a land exposed from a surface of the substrate and joined to the terminal portion, and a non-joined conductor not joined to the coil. The non-joined conductor is provided at a position overlapping with the body portion in a plan view seen in a thickness direction. An area of the non-joined conductor located directly below one of the coils may be smaller at directly below the end coil than at directly below the intermediate coil.

### BRIEF DESCRIPTION OF THE DRAWINGS

FIG. 1 is a circuit diagram showing a power supply circuit and an ECU to which an electronic device according to a first embodiment is applied.

FIG. 2 is a plan view showing the electronic device.

FIG. 3 is a see-through view of a coupled inductor in FIG. 2.

FIG. 4 is a perspective view showing the coupled inductor.

FIG. 5 is a plan view of the coupled inductor as viewed from the top side.

FIG. 6 is a plan view of the coupled inductor as viewed from the bottom side.

FIG. 7 is a perspective view showing a core.

FIG. 8 is a perspective view showing a coil.

FIG. 9 is a cross-sectional view taken along line IX-IX in FIG. 2.

FIG. 10 is a diagram showing a flow of magnetic flux when a current is passed through an intermediate coil.

FIG. 11 is a diagram showing a flow of magnetic flux when a current is passed through an end coil.

FIG. 12 is a plan view illustrating a modification.

FIG. 13 is a plan view showing a coupled inductor in an electronic device according to a second embodiment.

FIG. 14 is a diagram showing a positional relationship between a coupled inductor and a non-joined conductor.

FIG. 15 is a diagram showing a positional relationship between a coupled inductor and a non-joined conductor in an electronic device according to a third embodiment.

FIG. 16 is a cross-sectional view taken along line XVI-XVI in FIG. 15.

FIG. 17 is a plan view showing an electronic device according to a fourth embodiment.

FIG. 18 is a plan view showing an electronic device according to a fifth embodiment.

### DETAILED DESCRIPTION

A coupled inductor has multiple coils arranged in a specific direction and magnetically coupled to each other. The length of the magnetic path differs between the end coil and the intermediate coil, resulting in a difference in inductance between the end coil and the intermediate coil. An adjustment coil is disposed next to a coil in order to adjust the inductance. If an adjustment coil is disposed for the coupled inductor, the adjustment coil will be magnetically coupled with all the coils, such that the difference in inductance cannot be reduced between the end coil and the intermediate coil. In the above respects, and in other respects not mentioned, further improvements are desired in an electronic device that includes a coupled inductor.

The present disclosure provides an electronic device to reduce a difference in inductance.

According to an aspect of the present disclosure, an electronic device includes: a substrate having an insulating board and a conductor disposed on the insulating board; and a coupled inductor including a core and coils disposed in the core. The coils are arranged in a predetermined direction perpendicular to a thickness direction of the substrate, and magnetically coupled to each other. The coils include end coils located at ends in the predetermined direction and an intermediate coil located between the end coils. The coil has a body portion wound around the core and a terminal portion connected to the body portion. The conductor includes: a land exposed from a surface of the substrate and joined to the terminal portion; and a non-joined conductor not joined to the coil at a position overlapping with the body portion in a plan view seen in the thickness direction. An area of the non-joined conductor located directly below one of the coils is smaller at directly below the end coil than at directly below the intermediate coil.

In the electronic device, the magnetic path of the end coil is longer than the magnetic path of the intermediate coil. The longer the magnetic path, the lower the inductance of the coil. On the other hand, the non-joined conductor disposed immediately below the body portion of the coil absorbs a portion of the magnetic flux passing through the outside of the core. The larger the area of the non-joined conductor located directly below the coil, the smaller the magnetic flux and the smaller the inductance of the coil. According to the electronic device, the difference in inductance between the end coil and the intermediate coil can be reduced, since the non-joined conductor is arranged in consideration of the length of the magnetic path.

The embodiments disclosed in this description employ different technical means to achieve their respective objectives. Reference numerals exemplify the correspondence with portions of embodiments described later, and are not intended to limit the technical scope. The objects, features, and advantages disclosed in this description will become apparent by referring to following detailed descriptions and accompanying drawings.

Hereinafter, embodiments will be described with reference to the drawings. Duplicate description may be omitted by assigning the same reference numerals to the corresponding elements in each embodiment. In cases where only a part of the configuration is described in each embodiment, the configurations of other portions previously described in other embodiments may be applied to those parts. Further, not only the combinations of the configurations explicitly shown in the description of the respective embodiments, but also the configurations of the embodiments can be partially combined even if they are not explicitly shown if there is no problem in the combinations in particular.

### First Embodiment

An electronic device according to this embodiment includes a coupled inductor as described below. An electronic device including a coupled inductor can be applied to various electronic circuits such as a power supply circuit and a high-frequency circuit. The electronic device may be applied to an ECU including a power supply circuit or the like. ECU is an abbreviation for Electronic Control Unit.

### Power Supply Circuit and ECU

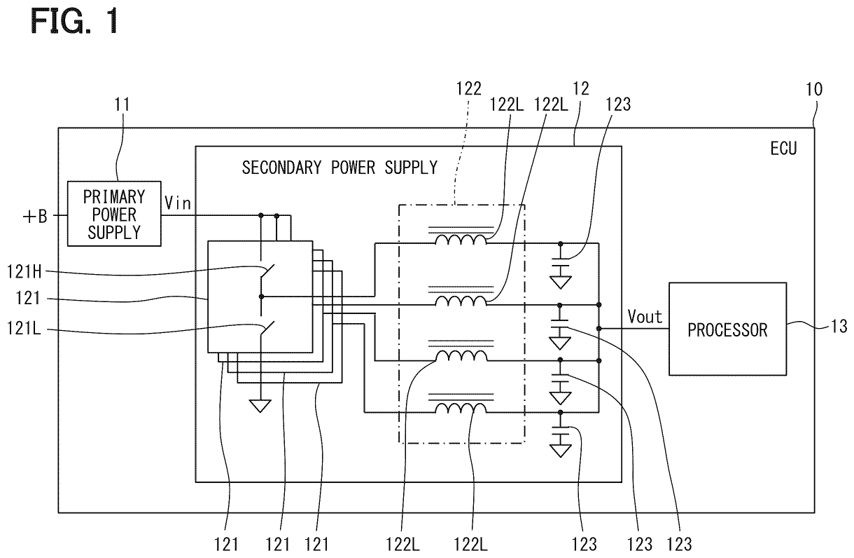

FIG. 1 is a circuit diagram showing an example of a power supply circuit and an ECU to which an electronic device according to the present embodiment is applied. For the sake of convenience, FIG. 1 shows a simplified view of some of drivers that constitute a secondary power supply circuit.

The ECU 10 includes a primary power supply circuit 11, a secondary power supply circuit 12, and a processor 13. An electronic device, which will be described later, may provide a portion of the secondary power supply circuit 12 or the entire secondary power supply circuit 12. The electronic device may provide a secondary power supply circuit 12 and a processor 13. The electronic device may provide the entire ECU 10. The ECU 10 may be installed, for example, in a mobile object. The mobile object may be a vehicle, a flying object, a ship, a construction machine, and an agricultural machine. The mobile object may be manned or unmanned.

The ECU 10 is installed in a vehicle. The ECU 10 may be, for example, an automated driving ECU or an ADAS ECU that executes control to assist the driver's driving operations. “ADAS” is an abbreviation for “Advanced Driving Assistant System”. For example, levels 3 to 5 as defined by the Society of Automotive Engineers (SAE International) correspond to automatic driving levels, while levels 1 to 2 correspond to driving assistance levels. The ECU 10 may also be an infotainment ECU or a cockpit ECU. The cockpit ECU controls devices such as a meter device, a navigation device, and an air conditioning device. The ECU 10 may be, for example, an integrated ECU that integrates plural control functions.

The primary power supply circuit 11 is configured to step down an input voltage to a predetermined voltage and output the voltage. The primary power supply circuit 11 is a step-down DC-DC converter. The primary power supply circuit 11 generates a constant voltage (for example, 5 V) lower than the power supply voltage (+B) based on power supplied from a battery mounted on the vehicle.

The secondary power supply circuit 12 uses the voltage generated by the primary power supply circuit 11 as an input voltage Vin. The secondary power supply circuit 12 steps down the input voltage Vin to a predetermined voltage (for example, about 1 V) and outputs it to a load as an output voltage Vout. The secondary power supply circuit 12 is a step-down DC-DC converter. The secondary power supply circuit 12 includes plural drivers 121, a coupled inductor 122, and a capacitor 123. The secondary power supply circuit 12 is a multi-phase power supply having multiple phases. A phase may be referred to as a stage, a channel, etc.

The driver 121 includes switching elements 121H, 121L. The switching elements 121H, 121L are connected in series between a power supply line to which an input voltage Vin is input and a ground (GND) line, with the switching element 121H on the high side and the switching element 121L on the low side. The switching element 121H, 121L may be, for example, MOSFET or IGBT. The switching element 121H, 121L could also be bipolar transistor. MOSFET is an abbreviation for metal oxide semiconductor field effect transistor. The IGBT is an abbreviation of an insulated gate bipolar transistor.

The coupled inductor 122 includes plural inductors 122L magnetically coupled to each other. One end of the inductor 122L is connected to a connection point (middle point) of the switching elements 121H, 121L. The other end of the inductor 122L is connected to the output line. The inductor 122L is provided separately for the driver 121. The driver 121 and the inductor 122L of each phase are connected in parallel to each other, to increase output current, i.e., load current, from a multiphase power supply. The number of phases of the multiphase power supply is not particularly limited. The multiphase power supply (secondary power supply circuit 12) has four phases.

The capacitor 123 is connected to the output line. A positive terminal of the capacitor 123 is connected to the output line. A negative terminal of the capacitor 123 is connected to ground. The capacitor 123 may be provided for each phase or in common to plural phases. The capacitor 123 is provided for each phase, such that the capacitor 123 is located close to the inductor 122L, thereby making it possible to shorten the return path from the capacitor 123. This makes it possible to improve emissions.

The ECU 10 may include a control unit (not shown) of the secondary power supply circuit 12. The control unit performs voltage mode control, for example, by feedback of the output voltage Vout, to control the operation of the driver 121, that is, the operation of the switching element 121H, 121L. The control unit determines the pulse width (duty ratio) of the PWM signal based on the output voltage Vout, and controls the output voltage Vout of the multiphase power supply. The control unit may execute current mode control, instead of voltage mode control. PWM is an abbreviation for Pulse Width Modulation.

The control unit synchronously controls the multiple drivers 121 so that the multiple drivers 121 perform switching operations in different phases from each other. By using multiple phases in this manner, it is possible to increase the switching frequency in a pseudo manner even if the switching frequencies of the multiple drivers 121 are the same. This makes it possible to reduce the ripple component of the output voltage Vout and improve the responsiveness. The control unit switches the driver 121 depending on the load current, to switch the number of driving phases. The control unit compares the load current with a threshold current, and increases and/or decreases the number of driving phases depending on the comparison result.

The processor 13 is an example of a load that operates by receiving power from the secondary power supply circuit 12. The processor 13 is, for example, a CPU, GPU, or the like. The CPU is an abbreviation for Central Processing Unit. The GPU is an abbreviation for Graphics Processing Unit. The ECU 10 may include only one processor 13 or multiple processors 13. The ECU 10 may include multiple types of processors 13. The processor 13 may be included in a SoC or a SiP. The SoC is a single semiconductor chip on which multiple components are mounted to realize the functions of a system or device. The SoC is an abbreviation for System on Chip. The SiP is an abbreviation for System in Package.

The processor 13 executes a control program stored in a memory (not shown) to perform predetermined processing for control. The memory is a non-transitory tangible storage medium that non-temporarily stores computer-readable programs, data, and the like.

A core voltage of the processor 13 is around 1V (for example, less than 1V), and the load current is several tens of amperes or more (for example, 100 A or more). In order to correspond to such low voltage and high current, the ECU 10 employs the multiphase power supply as its power circuit. The multiphase power supply steps down the input voltage to a voltage corresponding to the core voltage of the processor 13 and outputs the voltage. By using the multiphase power supply, it is possible to support enhanced performance of the processor 13 required for improvements in the automatic driving levels and evolution of infotainment functions, particularly automatic driving level 3 and above.

In a high-performance processor 13, current consumption fluctuates sharply in response to computational processing. Therefore, to ensure a stable voltage supply even during sudden load changes, a large number of capacitors 123 are required. By using the coupled inductor 122, magnetic fields between the phases can be cancelled out, and the effective inductance value can be reduced, improving responsiveness when the load suddenly changes. This allows the capacitor 123 to be significantly reduced as compared to a configuration using a normal single inductor. For example, since the size of the secondary power supply circuit 12 can be reduced, the size of the ECU 10 can be reduced.

### Outline Configuration of Electronic Device

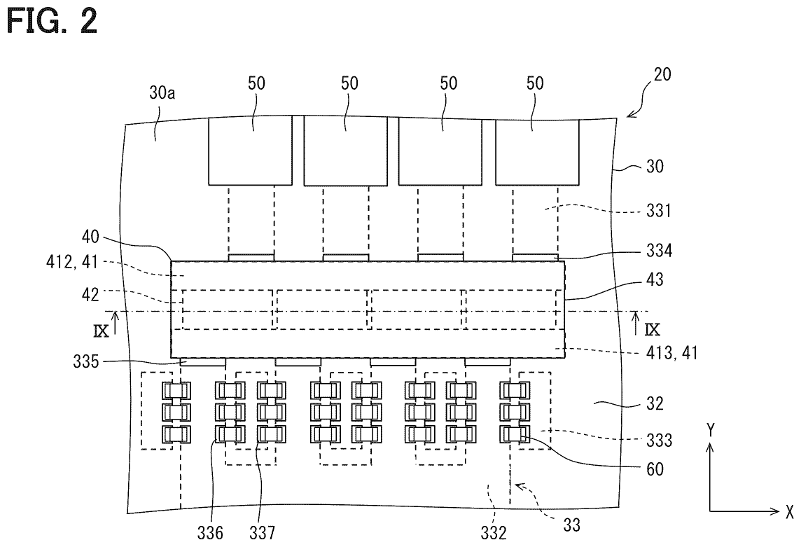

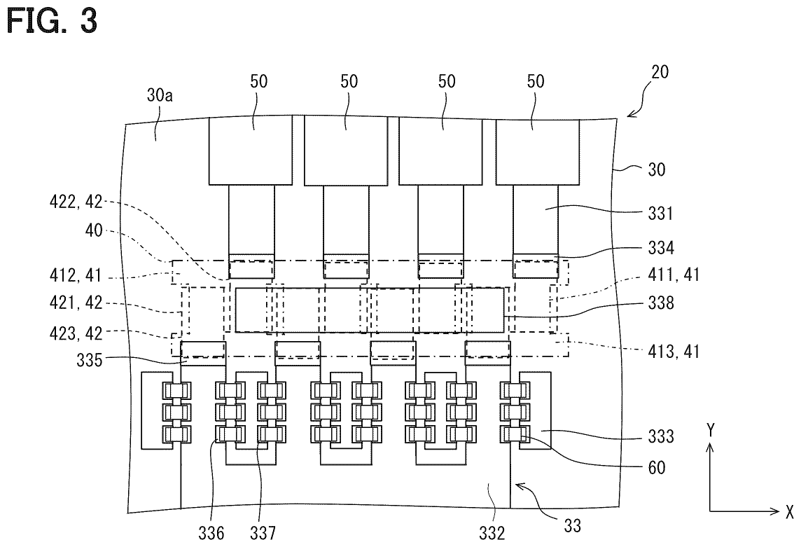

FIG. 2 is a plan view illustrating an example of the electronic device. FIG. 2 is an enlarged view of an area around the coupled inductor within the electronic device. In FIG. 2, the wiring covered with the resist is indicated by dashed lines. FIG. 3 is a perspective view of the coupled inductor, relative to FIG. 2. For convenience, the resist is omitted in FIG. 2. In FIG. 3, the outer periphery of the core is indicated by a single chain line, and the coil is indicated by a broken line.

As shown in FIGS. 2 and 3, the electronic device 20 includes a substrate 30 and plural components mounted on the substrate 30. The components include a coupled inductor 40, a switching device 50, and a capacitor 60. The electronic device 20 provides the multiphase power supply (secondary power supply circuit 12). The electronic device 20 may also provide the ECU 10. In this case, the processor 13 and the elements of the primary power supply circuit 11 are mounted on the substrate 30. The electronic device 20 may include a housing that houses the other elements that make up the electronic device 20.

Hereinafter, a thickness direction of the substrate is referred to as Z direction. A direction perpendicular to the Z direction and in which the coils are arranged is referred to as X direction. A direction perpendicular to both the Z direction and the X direction is referred to as Y direction. Unless otherwise specified, a shape viewed in a plane from the Z direction, that is, a shape along an XY plane defined by the X direction and Y direction is referred to as a planar shape. The planar view seen in the Z direction may be simply referred to as a plan view. A positional relationship in which B located below A overlaps with A in a plan view may be referred to as B being located directly below A.

The substrate 30 may be referred to as a printed circuit board, printed wiring board, or wiring board. The substrate 30 includes an insulating board 31, a resist 32, and a conductor 33. The insulating board 31 is formed using an electrically insulating material such as resin. The resist 32 is a so-called solder resist. The resist 32 covers a surface of the insulating board 31 in the Z direction on which the components are to be soldered. In the electronic device 20, the coupled inductor 40, the switching device 50, and the capacitor 60 are disposed on a first surface 30a of the substrate 30. The resist 32 is disposed on the insulating board 31 on at least the first surface 30a.

The conductor 33 is mounted on the insulating board 31. At least a portion of the conductor 33 forms a circuit together with the components mounted on the substrate 30. The conductor 33 includes a wiring. The wiring is formed by patterning a material such as metal foil. The wiring is disposed on at least the surface layer of the first surface 30a. The wiring may be disposed not only on the surface layer of the first surface 30a but also on the surface layer of the rear (second) surface, or may be disposed inside the insulating board 31. The substrate 30 may be a single-sided substrate, a double-sided substrate, or a multilayer substrate containing three or more layers of wiring. The conductor 33 may include, for example, a via conductor. The via conductor is formed by disposing a conductor such as plating in a through-hole (via) formed in an insulating layer of the insulating board 31. The via conductor electrically connects wires of different layers.

The substrate 30 is a multi-layer substrate. The wiring includes wirings 331, 332, 333 arranged on the surface layer of the first surface 30a. The wiring 331 electrically connects the coil 42 and the switching device 50. The wiring 331 is provided for each coil 42. The wiring 331 extends in the Y direction. The wirings 331 are arranged in the X direction.

The wiring 332 is an output wiring. The wiring 332 branches into plural parts at one end so that the parts can be individually connected to the coils 42, while the other ends are interconnected to form a common wiring. The branched portion of the wiring 332 electrically connects the coil 42 and the capacitor 60. The common wiring electrically connects the coil 42 and the capacitor 60 to the output terminal of the multiphase power supply. The wiring 332 extends in the Y direction. The wiring 332 has four branch portions. The branch portions are arranged in the X direction. The wiring 332 is provided at a position separated from the wiring 331 in the Y direction. The coupled inductor 40 is positioned between the wiring 332 and the wiring 331 in the Y direction.

The wiring 333 is a ground wire. The ground wiring provides a ground potential, which is a reference potential, on the substrate 30. The wiring 333 is electrically connected to an inner layer ground wiring via a via conductor (not shown), for example. The wiring 333 and the branched portion of the wiring 332 are arranged alternately in the X direction. The number of the wirings 333 is five.

The conductor 33 has lands 334, 335, 336, 337. The land is a portion of the wiring that is exposed from the resist 32 and that allows soldering to a component. The land may have an over-resist structure in which the outer periphery is covered with the resist 32 or a normal resist structure in which the outer periphery is not covered with the resist 32. The land 334, 335, 336, 337 is disposed on the surface layer of the insulating board 31 adjacent to the first surface 30a, to provide a wiring function.

The land 334, 335 is provided corresponding to the coil 42 of the coupled inductor 40. The land 334 is provided at the end of the wiring 331 adjacent to the coupled inductor 40. The land 335 is provided at the end of the wiring 332 adjacent to the coupled inductor 40. The land 334 is provided at a position separated from the land 335 in the Y direction. A terminal portion 422 of the coil 42 is joined to the land 334 via the solder 70, and a terminal portion 423 of the coil 42 is joined to the land 335 via the solder 70.

The substrate 30 has four lands 334 and four lands 335. The four lands 334 are arranged in the X direction. The four lands 335 are arranged in the X direction. The land 334 and the land 335 soldered to the same coil 42 are arranged with a shift in position in the X direction. The lands 334 and the lands 335 are arranged alternately in the X direction. The lands 334, 335 positioned adjacent to each other in the X direction may have a small gap therebetween, or their ends may be substantially aligned so that there is no gap between the land 334 and the land 335 in the X direction.

The land 336, 337 is provided corresponding to the capacitor 60. The land 336 is provided at the end in the X direction at the branched portion of the wiring 332. The lands 336 are provided on both ends of each branch portion in the X direction. The land 337 is provided at the end of the wiring 333 in the X direction. In the three wirings 333 located between the branched portions, the land 337 is provided at both ends in the X direction. In the wiring 333 located at both ends in the X direction, the land 337 is provided at location adjacent to one end facing the branched portion. The lands 336, 337 are provided to face each other in the X direction. The positive terminal of the capacitor 60 is soldered to the land 336, and the negative terminal of the capacitor 60 is soldered to the land 337.

The conductor 33 has a non-joined conductor 338 provided at a position overlapping with the coupled inductor 40 in a plan view. The non-joined conductor 338 will be described later.

The coupled inductor 40 is arranged on the first surface 30a of the substrate 30. The coupled inductor 40 provides the coupled inductor 122. The coupled inductor 40 has the core 41 and the coils 42. The coil 42 provides the inductor 122L. The coupled inductor 40 includes four coils 42. The coils 42 are arranged in the X direction. One end of the coil 42 is soldered to the land 334, and the other end of the coil 42 is soldered to the land 335. Details of the structure of the coupled inductor 40 will be described later.

The switching device 50 provides the driver 121, that is, the switching elements 121H, 121L. The switching device 50 is provided corresponding to the coil 42. The switching device 50 constitutes the switching elements 121H, 121L for one phase. A single switching device 50 constitutes the driver 121 for one phase. The switching device 50 may be a semiconductor package containing multiple semiconductor elements. Alternatively, the switching device 50 may be provided for each of the switching elements 121H, 121L. Multiple switching devices 50 are arranged in the X direction. The switching device 50 and the coupled inductor 40 are arranged in the Y direction. The switching device 50 is soldered to a land (not shown) provided at the end of the wiring 331 adjacent to the switching device 50.

The capacitor 60 provides the capacitor 123. The capacitor 60 is, for example, a chip capacitor. The coupled inductor 40 is positioned between the switching device 50 and the capacitor 60 in the Y direction. The positive terminal of the capacitor 60 is soldered to the land 336, and the negative terminal of the capacitor 60 is soldered to the land 337. The capacitor 60 is provided for each coil 42. The capacitors 60 are arranged to bridge adjacent wirings 332 and 333. The capacitors 60 corresponding to one coil 42 are arranged in the Y direction to form a capacitor row. The capacitors 60 corresponding to one coil 42 form a capacitor row. The capacitor rows are arranged in the X direction.

### Coupled Inductor

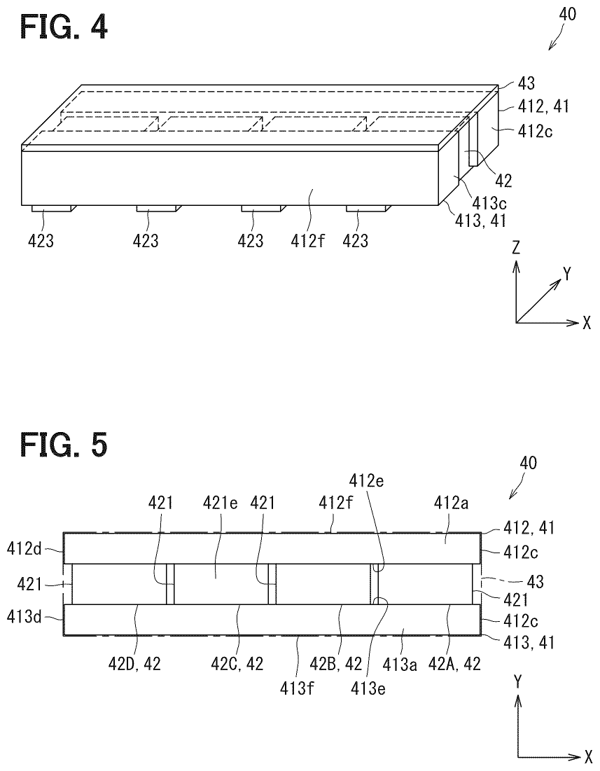

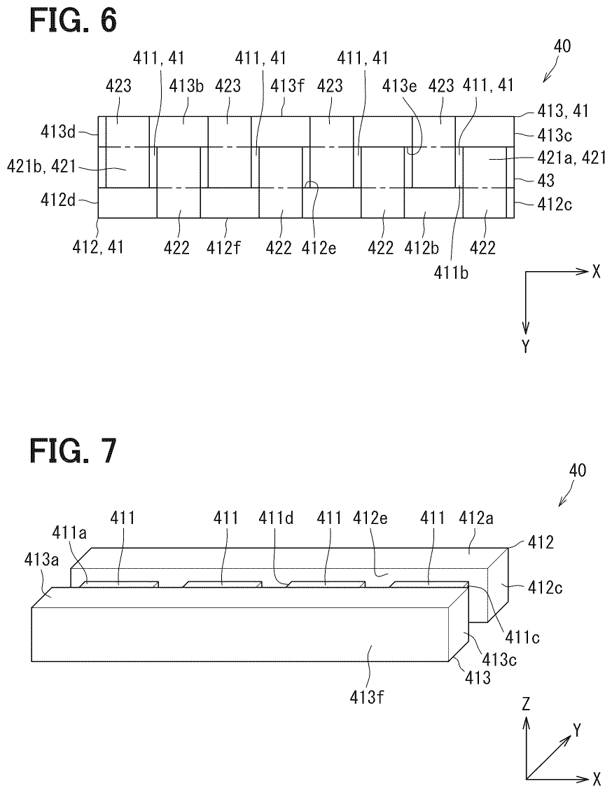

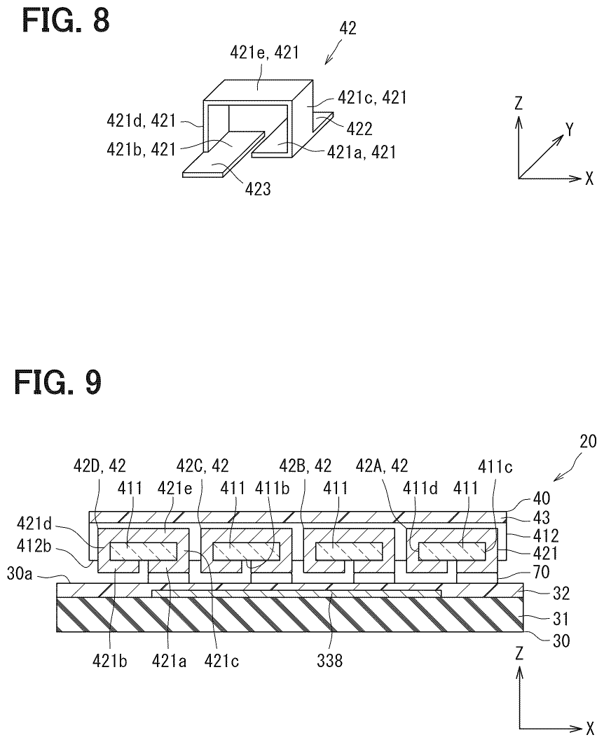

FIG. 4 is a perspective view illustrating a coupled inductor. FIG. 5 is a plan view of the coupled inductor as viewed from a top side. FIG. 6 is a plan view of the coupled inductor as viewed from a bottom side. In FIG. 6, the boundary between the body portion and the terminal is indicated by a dashed line. FIG. 7 is a perspective view illustrating a core. FIG. 8 is a perspective view illustrating a coil.

As shown in FIGS. 2 to 8, the coupled inductor 40 includes the core 41 and the coils 42. The coil 42 provides the inductor 122L. The coils 42 are arranged on the one core 41, that is, a common core 41, and are magnetically coupled to each other. By using the coupled inductor 40, a magnetic flux between phases can cancel each other out, thereby reducing the effective inductance.

The core 41 is formed using a magnetic material such as ferrite. The core 41 functions as a magnetic circuit. The core 41 has plural core portions 411 and end portions 412, 413. The core 41 passes through the coil 42. The core portion 411 is provided individually for each coil 42. The coil 42 is wound around the core portion 411. The core portion 411 extends in the Y direction. The core portions 411 are arranged in the X direction at predetermined interval. The core 41 has the four core portions 411. Each core portion 411 has a substantially rectangular parallelepiped shape. The four core portions 411 have the same shape.

The core portion 411 has an upper surface 411a, a lower surface 411b, and side surfaces 411c, 411d. The lower surface 411b is adjacent to the substrate 30 in the Z direction. The upper surface 411a is opposite to the lower surface 411b in the Z direction. The side surface 411c is opposite to the side surface 411d in the X direction.

The end portion 412 and the end portion 413 are disposed opposite to each other in the Y direction. The core portion 411 is interposed between the end portions 412 and 413. The end portion 412, 413 extends in the X direction in which the core portions 411 are arranged. One ends of the core portions 411 are connected to the end portion 412, and the other ends of the core portions 411 are connected to the end portion 413. The end portion 412, 413 magnetically couples the core portions 411 together. The end portions 412, 413 have the same shape as each other. The end portion 412, 413 is generally rectangular parallelepipeds with the X direction as the longitudinal direction.

The end portion 412 has an upper surface 412a, a lower surface 412b, and side surfaces 412c, 412d, 412e, 412f. The end portion 413 has an upper surface 413a, a lower surface 413b, and side surfaces 413c, 413d, 413e, 413f. The lower surface 412b, 413b is adjacent to the substrate 30 in the Z direction. The upper surface 412a, 413a is opposite to the lower surface 412b, 413b in the Z direction. The side surface 412c, 413c is opposite to the side surface 412d, 413d in the X direction. The side surfaces 412e, 413e face each other in the Y direction. The side surface 412f, 413f is opposite to the side surface 412e, 413e in the Y direction.

In the core 41, the lower surfaces 411b, 412b, 413b are substantially flush with each other. The upper surfaces 412a, 413a are farther from the substrate 30 than the upper surface 411a. The upper surface 411a is closer to the substrate 30 than the upper surface 412a, 413a.

The coil 42 is formed using a metal material with good conductivity, such as copper. The coil 42 is formed not by using a metal wire, but by processing a metal plate material. The metal plate material is sometimes referred to as a metal frame. The coils 42 are formed using the same material and have the same shape as each other. The coils 42 have approximately equal inductance. The coils 42 are arranged in the X direction with a predetermined interval. The coils 42 are aligned in the same orientation. The coils 42 are fixed to the core 41, for example, by adhesive bonding.

The coil 42 includes four coils 42A, 42B, 42C, 42D. The coils 42A, 42D are end coils located at the ends in the X direction. The coil 42A is located at the end adjacent to the side surface 412c, 413c. The coil 42D is located at the end adjacent to the side surface 412d, 413d. The coils 42B, 42C are intermediate coils located between the coil 42A and the coil 42D. The coil 42B is located next to the coil 42A. The coil 42C is located next to the coil 42D. The coils 42 are arranged in the X direction in the order of the coil 42A, the coil 42B, the coil 42C, and the coil 42D.

The coils 42 are formed by bending a metal plate material of a predetermined thickness. The coil 42 has a body portion 421 and terminal portions 422, 423. The terminal portion 422, 423 is an external connection terminal of the coil 42 and soldered to the corresponding land 334, 335. The terminal portion 422 is soldered to the land 334, and the terminal portion 423 is soldered to the land 335. The thickness direction of the terminal portion 422, 423 is approximately parallel to the Z direction, and the lower surface, which is one of the plate surfaces, of the terminal portion 422, 423 faces the first surface 30a of the substrate 30. The other of the plate surfaces of the terminal portion 422, that is, an upper surface, faces the lower surface 412b of the end portion 412. The upper surface of the terminal portion 423 faces the lower surface 413b of the end portion 413.

The terminal portion 422, 423 has a generally rectangular shape in a plan view. The terminal portion 422 is continuous with the bottom wall 421a of the body portion 421 and extends in the Y direction toward the side surface 412f, that is, toward the switching device 50. The terminal portion 423 is connected to the bottom wall 421b of the body portion 421 and extends in the Y direction, in the opposite direction to the terminal portion 422. The terminal portion 423 extends toward the side surface 413f, that is, toward the capacitor 60. The terminal portions 422 and 423 connected to the same body portion 421 are arranged with a shift in the Y direction. The terminal portions 422 and 423 connected to the same body portion 421 are arranged with a shift in the X direction. The terminal portion 422 has approximately the same length in the Y direction as the end portion 412. The terminal portion 423 has approximately the same length in the Y direction as the end portion 413. The terminal portion 422, 423 may extend outward beyond the corresponding end portion 412, 413 in a plan view.

The body portion 421 is wound around the core portion 411 of the core 41. The body portion 421 overlaps with the core portion 411 in a plan view. The body portion 421 has bottom walls 421a, 421b, side walls 421c, 421d, and an upper wall 421e.

The thickness direction of the bottom wall 421a, 421b is approximately parallel to the Z direction. The lower surface, which is one of the plate surfaces of the bottom walls 421a, 421b, faces the first surface 30a of the substrate 30, and the other upper surface, which is the other of the plate surfaces, faces the lower surface 411b of the core portion 411. The bottom wall 421a, 421b is generally rectangular in a plan view. The terminal portion 422 is connected to the end of the bottom wall 421a adjacent to the side surface 412f. The bottom wall 421a and the terminal portion 422 extend along the Y direction. The terminal portion 423 is connected to the end of the bottom wall 421b adjacent to the side surface 413f. The bottom wall 421b and the terminal portion 423 extend along the Y direction. The bottom wall 421a, 421b has approximately the same length as the core portion 411 in the Y direction. The bottom wall 421a, 421b of one body portion 421 are arranged in the X direction.

The side wall 421c is continuous with the bottom wall 421a. The side wall 421c extends in the Z direction from the bottom wall 421a. The side wall 421c faces the side surface 411c of the core portion 411. The side wall 421c has a substantially rectangular shape when viewed in a plan view along the X direction. The side wall 421c has approximately the same length in the Y direction as the bottom wall 421a. The side wall 421c is bent to form an angle of approximately 90 degrees with respect to the bottom wall 421a. The thickness direction of the side wall 421c is approximately parallel to the X direction. The lower end of the side wall 421c is continuous with the end of the bottom wall 421a opposite to the end facing the bottom wall 421b.

The side wall 421d is continuous with the bottom wall 421b. The side wall 421d extends in the Z direction from the bottom wall 421b. The side wall 421d faces the side surface 411d of the core portion 411. The side wall 421d has a substantially rectangular shape when viewed in a plan view along the X direction. The side wall 421d has approximately the same length in the Y direction as the bottom wall 421b. The side wall 421d is bent to form an angle of approximately 90 degrees with respect to the bottom wall 421b. The thickness direction of the side wall 421d is approximately parallel to the X direction. The lower end of the side wall 421d is continuous with the end of the bottom wall 421b opposite to the end facing the bottom wall 421a.

The upper wall 421e bridges the side walls 421c, 421d. The upper wall 421e extends in the X direction. One end of the upper wall 421e is continuous with the upper end of the side wall 421c, and the other end is continuous with the upper end of the side wall 421d. The upper wall 421e has the same length in the Y direction as the side walls 421c, 421d. In a plan view, the upper wall 421e includes the entire side walls 421c, 421d and the entire bottom walls 421a, 421b.

The bottom walls 421a, 421b, the side walls 421c, 421d, and the upper wall 421e surround the core portion 411 of the core 41. The bottom walls 421a, 421b, the side walls 421c, 421d, and the upper wall 421e are attached to and wound around the core portion 411. The end portions 412, 413 of the core 41 are disposed on the terminal portions 422, 423. A part of the terminal portion 422, 423 is located closer to the substrate 30 than the lower surfaces 411b, 412b, 413b of the core 41. The lower surfaces of the terminal portions 422, 423 are located closer to the first surface 30a than the lower surfaces 411b, 412b, 413b of the core 41.

In the coils 42 adjacent to each other, one side wall 421c of the coil 42 faces the other side wall 421d of the coil 42. In the coupled inductor 40, the outer surface of the side wall 421c located adjacent to the one end of the coupled inductor 40 is recessed with respect to the side surface 412c, 413c. Similarly, the outer surface of the side wall 421d located adjacent to the other end of the coupled inductor 40 is recessed with respect to the side surface 412d, 413d. The upper surface of the upper wall 421e of the coil 42 is recessed with respect to the upper surface 412a, 413a.

For example, the outer surface of the side wall 421c adjacent to the one end may be made substantially flush with the side surfaces 412c, 413c. The outer surface of the side wall 421d adjacent to the other end may be made substantially flush with the side surfaces 412d, 413d. The upper surface of the upper wall 421e may be made substantially flush with the upper surfaces 412a, 413a.

In addition to the core 41 and the coils 42, the coupled inductor 40 may include a cover. The coupled inductor 40 includes the cover 43. The cover 43 is disposed on the upper surface of the core 41 and covers the core 41 and the coils 42. The cover 43 is used, for example, for the purpose of suppressing adhesion of foreign matter to the coupled inductor 40. The cover 43 is used for the purpose of preventing short circuits between the coils 42 caused by conductive foreign matter, for example. The cover 43 is used for the purpose of increasing the adhesiveness during transportation when the coupled inductor 40 is mounted on the substrate 30, for example.

The material of the cover 43 is not particularly limited as long as the object can be achieved. For example, the cover 43 may be made of resin or magnetic material. The cover 43 may be made of the same material as the core 41. The cover 43 may function as a part of the core 41. An example of the cover 43 is a resin film or a resin sheet. The cover 43 has a generally rectangular shape in a plan view with its longitudinal direction aligned in the X direction. The cover 43 is provided to enclose the core 41 and the coils 42 in a plan view. The cover 43 is adhesively fixed to the upper surfaces 412a, 413a of the end portions 412, 413.

### Non-Joined Conductor

FIG. 9 is a cross-sectional view taken along line IX-IX of FIG. 2. As shown in FIGS. 3 and 9, the substrate 30 includes the non-joined conductor 338. The non-joined conductor 338 is not joined to the coil 42. The non-joined conductor 338 is provided at a position overlapping the body portion 421 of the coil 42 in a plan view. The non-joined conductor 338 is located directly below the body portion 421. The non-joined conductor 338 may be provided only directly below the body portion 421, or may be provided to extend from directly below the body portion 421 to directly below a non-mounted portion of the terminal portion 422, 423. The non-mounted portion of the terminal portion 422, 423 is a portion excluding the mounted portion soldered to the land 334, 335. The non-joined conductor 338 is arranged so that the area of the non-joined conductor 338 located directly below one coil 42 is smaller at directly below the end coil than at directly below the intermediate coil.

The non-joined conductor 338 is disposed on the surface layer of the substrate 30 adjacent to the first surface 30a, similar to the wiring 331, 332 and the land 334, 335. The non-joined conductor 338 is covered by the resist 32. The non-joined conductor 338 is spaced apart from the land 334, 335. The non-joined conductor 338 is electrically isolated from the wiring of the circuit. The non-joined conductor 338 is provided only directly below the body portion 421. The non-joined conductor 338 has a generally rectangular shape in a plan view with its longitudinal direction aligned in the X direction. The non-joined conductor 338 extends in the X direction to overlap with the four coils 42A, 42B, 42C, 42D. The substrate 30 has one non-joined conductor 338 located directly below the body portion 421 across the four coils 42A, 42B, 42C, 42D.

The non-joined conductor 338 overlaps substantially the entire body portion 421 of the coil 42B, which is the intermediate coil, in a plan view. The non-joined conductor 338 overlaps substantially the entire body portion 421 of the coil 42C, which is the intermediate coil, in a plan view. The non-joined conductor 338 overlaps a portion of the body portion 421 of the coil 42A, which is an end coil, in a plan view. The non-joined conductor 338 overlaps a portion of the bottom wall 421b, the side wall 421d, and a portion of the upper wall 421e of the body portion 421 of the coil 42A. The non-joined conductor 338 overlaps a portion of the body portion 421 of the coil 42D, which is an end coil, in a plan view. The non-joined conductor 338 overlaps a portion of the bottom wall 421a, the side wall 421c, and a portion of the upper wall 421e of the body portion 421 of the coil 42D. The non-joined conductor 338 overlaps the entire length of the coil 42B, 42C in the X direction. The non-joined conductor 338 overlaps a portion of the coil 42A, 42D in the X direction.

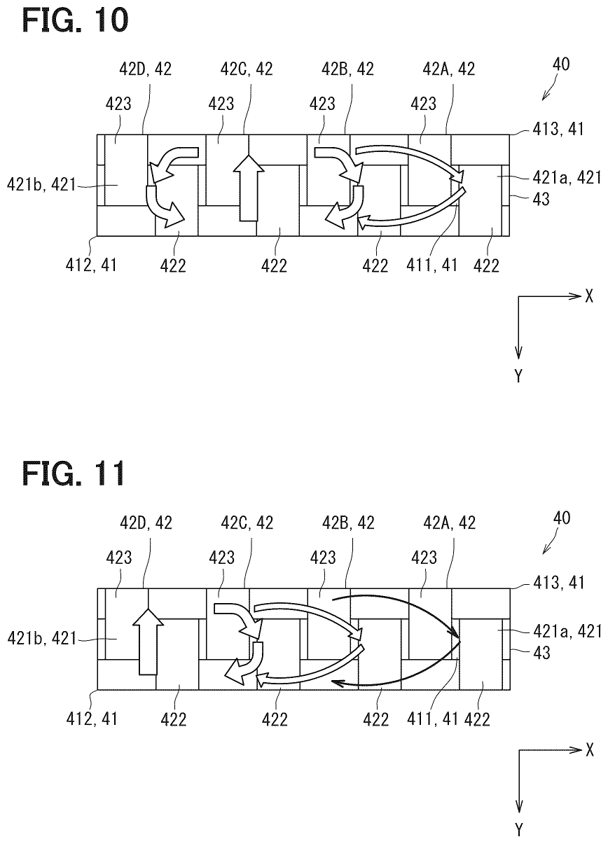

FIGS. 10 and 11 are diagrams showing the flow of magnetic flux. FIG. 10 shows the flow of magnetic flux when a current is passed through the coil 42C, which is the intermediate coil. FIG. 11 shows the flow of magnetic flux when a current is passed through the coil 42D, which is an end coil. In FIGS. 10 and 11, the flow of magnetic flux is indicated by the solid arrow. The magnitude of the magnetic flux is indicated by the thickness of the solid arrow. A non-joined conductor is not provided in FIG. 10 and FIG. 11.

When a current flows through one of the coils 42, a loop-shaped magnetic path is formed through the core portion 411 around which the other coils 42 are wound. Here, the inductance L of the coil is given by Formula 1, and the magnetic resistance Rm is given by Formula 2, where N is the number of turns in the coil, l is the length of the magnetic path, μ₀ is the magnetic permeability of a vacuum, μ is the magnetic permeability, and S is the cross-sectional area of the magnetic path. It is clear from Formulas 1 and 2 that the magnetic resistance Rm increases as the length l of the magnetic path increases, and the increase in magnetic resistance Rm reduces the magnetic flux generated by the same current, thereby decreasing the inductance L.

$$L = {N}^{2} / Rm \qquad Formula 1$$

$$Rm = I / {μ}_{0} μ S \qquad Formula 2$$

As shown in FIGS. 10 and 11, the coil 42D (end coil) has a longer magnetic path than the coil 42C (intermediate coil), and therefore the inductance of the coil 42D is lower than the inductance of the coil 42C. When the inductance is actually measured, the inductance of the end coil is about 8% lower than that of the intermediate coil.

In a multiphase power supply using the coupled inductor 40, if the inductance values of the coils 42 differ, the current variation between the phases becomes large. There is also a difference in mutual inductance. This causes the current generated by the magnetic coupling to vary, resulting in increased EMI. EMI is an abbreviation for Electromagnetic Interference.

The electronic device 20 of this embodiment includes the substrate 30 and the coupled inductor 40. The coupled inductor 40 has the core 41 and the coils 42 disposed on the core 41. The coils 42 are arranged in a predetermined direction perpendicular to the thickness direction of the substrate 30, and magnetically coupled to each other. The coils 42 include end coils located at the ends in the predetermined direction and an intermediate coil located between the end coils. The coil 42 has a body portion 421 wound around the core 41 and the terminal portion 422, 423 connected to the body portion 421. The conductor 33 of the substrate 30 includes the land 334, 335 exposed on the first surface 30a of the substrate 30 and joined to the terminal portion 422, 423, and the non-joined conductor 338 positioned to overlap with the body portion 421 when viewed in a plan view along the thickness direction and not joined to the coil 42. The area of the non-joined conductor 338 located directly below one of the coils 42 is smaller directly below the end coil than directly below the intermediate coil. In the electronic device 20, the coils 42A, 42D correspond to end coils, and the coils 42B, 42C correspond to intermediate coil. The Z direction corresponds to the thickness direction of the substrate 30, and the X direction corresponds to the predetermined direction.

In the electronic device 20, the magnetic path of the end coil is longer than the magnetic path of the intermediate coil. The longer the magnetic path, the smaller the inductance of the coil 42. On the other hand, the non-joined conductor 338 disposed directly below the body portion 421 of the coil 42 absorbs a portion of the magnetic flux passing through the outside of the core 41. The larger the area of the non-joined conductor 338 located directly below the coil 42, the smaller the magnetic flux becomes, and the smaller the inductance of the coil 42 becomes. By making the area of the non-joined conductor 338 directly below the end coil smaller than the area of the non-joined conductor 338 directly below the intermediate coil, the absorption of magnetic flux by the non-joined conductor 338 is weakened in the end coil more than in the intermediate coil, and the decrease in inductance due to the magnetic flux absorption can be suppressed more in the end coil than in the intermediate coil. In this embodiment, the non-joined conductor 338 is arranged, in contrast to the length of the magnetic path, so that the difference in inductance between the end coil and the intermediate coil can be reduced.

The non-joined conductor 338 may be located directly below the end coil as well as directly below the intermediate coil. This makes it possible to adjust the area of the non-joined conductor 338 immediately below the end coil relative to the area of the non-joined conductor 338 immediately below the intermediate coil. This increases the degree of freedom in adjusting the inductance.

### Modifications

The relationship between the area of the non-joined conductor 338 per intermediate coil and the area of the non-joined conductor 338 per end coil is not limited to the example described above.

The areas of the non-joined conductors 338 are substantially equal to each other relative to the multiple intermediate coils, and the areas of the non-joined conductors 338 are substantially equal to each other relative to the multiple end coils, but not limited to this. In order to eliminate differences in inductance caused by manufacturing variations in the coupled inductor 40, the areas of the non-joined conductors 338 may be made different among the multiple intermediate coils. Similarly, the areas of the non-joined conductors 338 may be different among the multiple end coils.

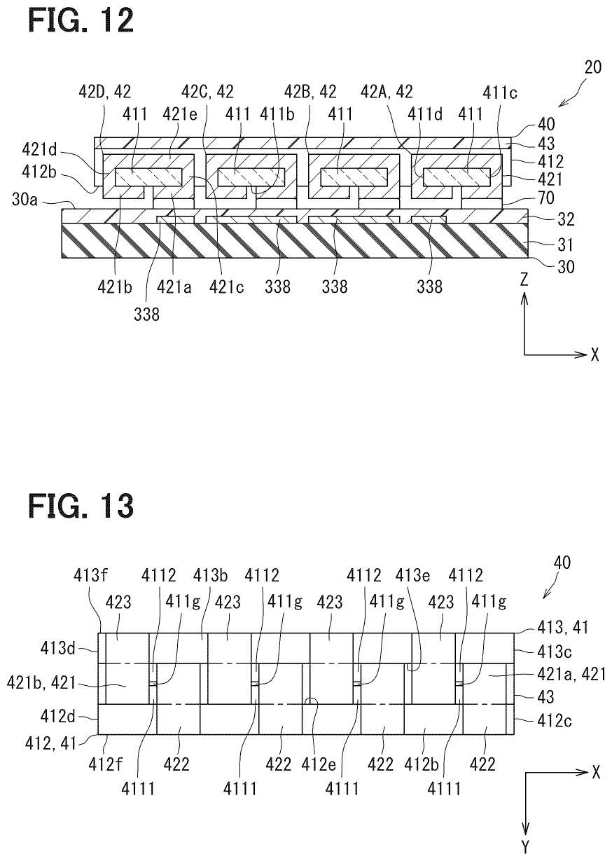

A part of one non-joined conductor 338 is disposed directly below the intermediate coil and another part is disposed directly below the end coil, but not limited to this. The substrate 30 may have plural non-joined conductors 338. For example, as shown in FIG. 12, the non-joined conductors 338 may be respectively disposed relative to the coils 42. In FIG. 12, the substrate 30 has four non-joined conductors 338. Although not shown in the figure, at least a part of the non-joined conductors 338 corresponding to the multiple intermediate coils may be integrated. For example, in FIG. 12, the non-joined conductors 338 corresponding to the two intermediate coils may be integrated, so that the substrate 30 has three non-joined conductors 338.

The non-joined conductor 338 is disposed on the surface layer, but not limited to this. The non-joined conductor 338 may not be disposed on the surface layer, but may be disposed, for example, on the second or subsequent layer. The closer the non-joined conductor 338 is to the coil 42, the stronger the magnetic coupling. By disposing the non-joined conductor 338 on the surface layer, the effect on inductance due to the difference in area can be increased.

### Second Embodiment

The present embodiment is a modification of the preceding embodiment and can incorporate the contents of the preceding embodiment. In the previous embodiment, the core is not divided. Alternatively, the core may be divided into multiple parts. In the previous embodiment, the non-joined conductor overlaps a part of each end coil in the X direction. Alternatively, the non-joined conductor may overlap the end coil over the entire length.

FIG. 13 is a plan view showing a coupled inductor in the electronic device according to this embodiment. FIG. 13 corresponds to FIG. 6. As shown in FIG. 13, in the coupled inductor 40 of this embodiment, the core portion 411 of the core 41 is divided into plural portions. The core portion 411 is divided into the plural parts in the Y direction in which the end portions 412, 413 oppose to each other. The core portion 411 is divided at the center position in the Y direction. The core portion 411 includes two core portions 4111, 4112. The lengths of the core portions 4111, 4112 in the Y direction are approximately equal to each other.

The core portion 4111 is connected to the end portion 412. The core portion 4111 extends from the side surface 412e of the end portion 412 toward the end portion 413. The core portion 4112 is connected to the end portion 413. The core portion 4112 extends from the side surface 413e of the end portion 413 toward the end portion 412. The end portion 412 corresponds to a first end, and the end portion 413 corresponds to a second end. The core 41 has a gap 411g between the opposing surfaces of the core portion 4111 and the core portion 4112, in which no magnetic member is disposed. An adhesive, for example, is placed in the gap 411g to fix the core portion 4111 and the core portion 4112 together.

The division position is not limited to the center. A single core portion 411 may be connected to one of the end portions 412, 413 and bonded to the other. A single core portion 411 may be bonded at both ends to the end portions 412, 413, respectively. The core portion 411 may be divided into three or more portions.

If the core portion 411 has the gap 411g, magnetic flux will leak from the gap 411g. The coil 42 is wound around the core portion 411. However, the coil 42 (conductor) is not present in the region between the bottom wall 421a and the bottom wall 421b. Therefore, magnetic flux is likely to leak particularly from the position where the gap 411g overlaps with the region between the bottom walls 421a and 421b. Leakage flux worsens emissions.

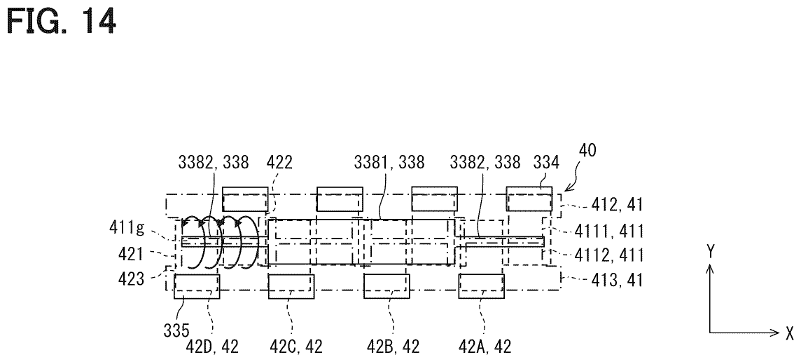

FIG. 14 is a diagram showing the positional relationship between the coupled inductor and the non-joined conductor in the electronic device according to this embodiment. In FIG. 14, the coupled inductor is shown in a see-through manner. In FIG. 14, the resist is omitted. For convenience, the cover is omitted in FIG. 14. The outer periphery of the core is indicated by a single chain line, and the coil is indicated by a broken line. FIG. 14 also shows the land on which the coupled inductor is mounted. In FIG. 14, magnetic flux is indicated by a solid arrow.

The electronic device 20 includes the non-joined conductor 338 arranged to overlap the body portion 421 of the coil, similar to the previous embodiment. As in the previous embodiment, the non-joined conductor 338 is arranged to overlap almost the entire area of each of the intermediate coils 42B, 42C, and is arranged to overlap a part of each of the end coils 42A, 42D. In the X direction, the non-joined conductor 338 is disposed to overlap the body portion 421 of the coil 42A over the entire length of the coil 42A. The non-joined conductor 338 is arranged to overlap the body portion 421 of the coil 42D over the entire length of the coil 42D.

The non-joined conductor 338 has a widened portion 3381 and a narrowed portion 3382. The widened portion 3381 is longer than the narrowed portion 3382 in the Y direction. The narrowed portion 3382 is shorter than the widened portion 3381 in the Y direction. The widened portion 3381 is disposed to overlap the coil 42B, 42C in a plan view. The length of the widened portion 3381 in the Y direction is approximately equal to the length of the body portion 421 in the Y direction. The narrowed portion 3382 is disposed to overlap the coil 42A, 42D in a plan view. The length of the narrowed portion 3382 in the Y direction is shorter than the length of the body portion 421 in the Y direction. The widened portion 3381 extends in the X direction with its width, which is its length in the Y direction, constant. The narrowed portion 3382 has a constant width and extends in the X direction. The widened portion 3381 has a generally rectangular shape in a plan view. The narrowed portion 3382 has a generally rectangular shape in a plan view. The narrowed portion 3382 is continuous with both ends of the widened portion 3381 in the X direction.

The non-joined conductor 338 is arranged to overlap at least one gap 411g of the core portions 411 in a plan view. The non-joined conductor 338 is provided to overlap at least a portion of the gap 411g in one core portion 411. In the electronic device 20, the non-joined conductor 338 is arranged to overlap all of the gaps 411g of the corresponding core portions 411. The non-joined conductor 338 is arranged in all of the core portions 411 to overlap all of the gaps 411g. The widened portion 3381 overlaps the entire gap 411g of the coil 42B and the entire gap 411g of the coil 42C in a plan view. The narrowed portion 3382 overlaps the entire gap 411g of the coil 42A and the entire gap 411g of the coil 42D in a plan view. Since the non-joined conductor 338 is present directly below the gap 411g, leakage of magnetic flux from the gap 411g can be suppressed. Other configurations are the same as the configurations described in the preceding embodiment.

The non-joined conductor 338 may be arranged to overlap the body portion 421 of the end coil over its entire length in a predetermined direction. In the electronic device 20, the X direction corresponds to the predetermined direction. The coils 42A, 42D correspond to end coils. The non-joined conductor 338 is evenly spaced, rather than being biased relative to the end coil in the X direction. This makes it possible to uniformize the magnetic coupling between the non-joined conductor 338 and the end coil, thereby improving the accuracy of inductance adjustment. Therefore, the effect of reducing the inductance difference can be enhanced.

The core portion 411 of the core 41 of the coupled inductor 40 may be divided into plural parts in the perpendicular direction, and may have the gap 411g. The non-joined conductor 338 corresponding to the end coil may be arranged to overlap the gap 411g of the end coil in a plan view. According to this, leakage of magnetic flux from the gap 411g can be suppressed by the non-joined conductor 338 (narrowed portion 3382) disposed to oppose the gap 411g. By providing the non-joined conductor 338, leakage of magnetic flux can be suppressed compared to a configuration in which the non-joined conductor 338 is not provided, that is, a configuration in which air is present. The effect can be enhanced by arranging the non-joined conductor 338 to face the gap 411g. This allows the inductance to be adjusted.

The non-joined conductor 338 may be disposed in a portion of the gap 411g that overlaps with a region between the bottom walls 421a, 421b of the coil 42 in a plan view. The conductor of the coil 42 is wound around the core portion 411. However, the bottom walls 421a, 421b are disposed with a predetermined gap therebetween. Therefore, magnetic flux is likely to leak from the gap 411g that overlaps with the region between the bottom walls 421a, 421b. The leakage of magnetic flux can be effectively suppressed by disposing the non-joined conductor 338 in the gap 411g, particularly in the area overlapping with the region between the bottom walls 421a, 421b.

The non-joined conductor 338 may be arranged to overlap all of the gap 411g in one core portion 411. Since the non-joined conductor 338 is disposed to face the entire area of the gap 411g, leakage of magnetic flux can be more reliably suppressed.

The non-joined conductor 338 may be arranged to overlap at least a portion of each of the gaps 411g of the core portions 411. Since the non-joined conductor 338 is disposed to face all of the gaps 411g, leakage magnetic flux can be suppressed throughout the coupled inductor 40.

### Modifications

For example, in case where the core portion 411 is not divided into plural parts, the non-joined conductor 338 may be arranged to overlap the body portion 421 of the end coil over its entire length in a predetermined direction.

In case where the non-joined conductor 338 is divided into plural parts, the non-joined conductor 338 corresponding to the end coil may be arranged to overlap the body portion 421 over the entire length in a predetermined direction.

### Third Embodiment

The present embodiment is a modification of the preceding embodiment and can incorporate the contents of the preceding embodiment. In the previous embodiment, the non-joined conductor is placed directly below the end coil. Alternatively, no non-joined conductor is disposed directly below the end coil.

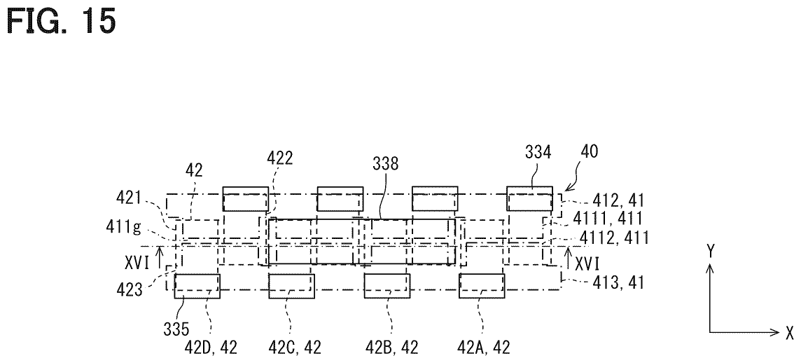

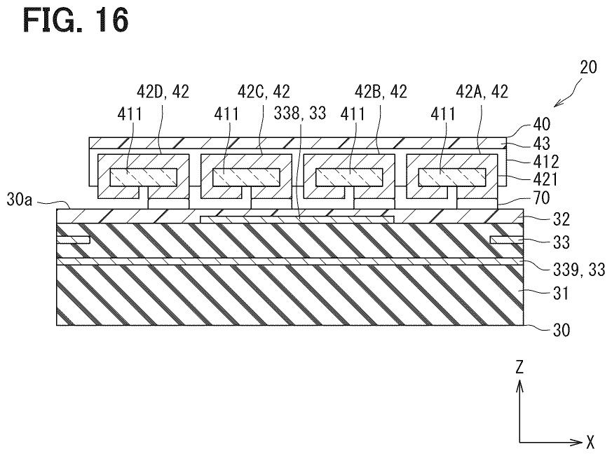

FIG. 15 is a plan view showing a coupled inductor in the electronic device according to this embodiment. FIG. 15 corresponds to FIG. 14. In FIG. 15, the coupled inductor is shown in a see-through manner. Moreover, the resist is omitted. For convenience, the cover is omitted in FIG. 15. The outer periphery of the core is indicated by a single chain line, and the coil is indicated by a broken line. FIG. 15 shows the land on which the coupled inductor is mounted. FIG. 16 is a cross-sectional view taken along line XVI-XVI in FIG. 15.

As shown in FIGS. 15 and 16, the non-joined conductor 338 is disposed directly below the body portion 421 of the coil 42B, 42C. The non-joined conductor 338 is not disposed directly below the body portion 421 of the coil 42A, 42D. In the electronic device 20, the non-joined conductor 338 has a generally rectangular planar shape. The non-joined conductor 338 overlaps the entire area of the body portion 421 of the coil 42B, 42C. The non-joined conductor 338 is disposed to overlap the gap 411g between the coils 42B and 42C.

As shown in FIG. 16, the non-joined conductor 338 is disposed on the surface layer of the substrate 30 adjacent to the first surface 30a, similar to the land 334, 335. In the surface layer, the non-joined conductor 338 is disposed directly below the coil 42B, 42C, but is not disposed directly below the coil 42A, 42D. In the second layer, which is located next to the surface layer, the conductor 33 is not disposed directly below the coil 42A, 42D. In other words, the conductor 33 that can function as the non-joined conductor 338 is not present in either the surface layer (first layer) or the second layer directly below the coil 42A, 42D.

In FIG. 16, the conductor 33 in the second layer is not disposed directly below the coil 42B, 42C. Alternatively, the conductor 33 in the second layer may be disposed directly below the coil 42B, 42C. The substrate 30 has a ground wiring 339 arranged in the third layer. The ground wiring 339 is arranged over a wide area. The ground wiring 339 is sometimes called an inner layer ground or a solid ground. The ground wiring 339 is arranged to overlap the body portions 421 of all the coils 42 in a plan view. The conductor 33 that can function as the non-joined conductor 338 is not present in a layer directly below the coil 42A, 42D that is closer to the first surface 30a than the ground wiring 339. Other configurations are the same as the configurations described in the preceding embodiment.

The non-joined conductor 338 may be positioned directly below the intermediate coil and not directly below the end coil, so that the area of the non-joined conductor 338 positioned directly below one coil 42 may be smaller at directly below the end coil than at directly below the intermediate coil. By eliminating the non-joined conductor 338 immediately below the end coil, the absorption of magnetic flux by the non-joined conductor 338 can be further weakened, and a decrease in inductance of the end coil can be suppressed. In other words, by not providing the non-joined conductor 338 directly below, the inductance of the end coil can be made larger than in a configuration in which the non-joined conductor 338 is provided. This makes it possible to reduce the difference in inductance between the intermediate coil and the end coil.

When the effect of the presence or absence of the non-joined conductor 338 on inductance is actually measured for one coil 42, if the non-joined conductor 338 is not provided, the inductance increased by approximately 5.5% compared to a configuration in which the non-joined conductor 338 overlapping the entire body portion 421 is provided. In this manner, it is confirmed that the absence of the non-joined conductor 338 can suppress the decrease in inductance due to the absorption of magnetic flux.

In the layer of the substrate 30 on which the land 334, 335 is arranged, the non-joined conductor 338 is arranged directly below the intermediate coil, but not directly below the end coil. By arranging the non-joined conductor 338 on the layer on which the land 334, 335 is arranged, i.e., on the surface layer, the non-joined conductor 338 is brought closer to the coil 42. Therefore, the absorption of magnetic flux by the non-joined conductor 338 can be improved. In other words, the difference in inductance between the presence and absence of the non-joined conductor 338 can be increased.

The non-joined conductor 338 may not be present, for example, in the surface layer and the second layer of the multiple layers continuous from the surface layer, at directly below the end coil. By not arranging the non-joined conductor 338 in the layer deeper than the surface layer, the magnetic coupling between the end coil and the non-joined conductor 338 can be further weakened. Therefore, the effect of reducing the difference in inductance between the intermediate coil and the end coil can be enhanced.

### Modifications

The non-joined conductor 338 is not limited to be disposed on the surface layer. The non-joined conductor 338 may not be disposed on the surface layer, but may be disposed, for example, on the second layer. In the second layer, the non-joined conductor 338 may be patterned to be located directly below the coil 42B, 42C, but not directly below the coil 42A, 42D.

A part of the ground wiring 339 may be a non-joined conductor 338. For example, the ground wiring 339 may be patterned to overlap the coil 42B, 42C in a plan view, but not to overlap the coil 42A, 42D.

As shown in the previous embodiment, the non-joined conductor 338 may be provided separately for the coil 42. In the configuration shown in FIG. 15, the non-joined conductor 338 located immediately below the coil 42B and the non-joined conductor 338 located immediately below the coil 42C may be separated.

### Fourth Embodiment

The present embodiment is a modification based on the preceding embodiment and can incorporate the contents of the preceding embodiment. In the previous embodiment, the non-joined conductor is separated from the wiring of the circuit. Alternatively, a portion of the wiring that provides the predetermined potential may be a non-joined conductor.

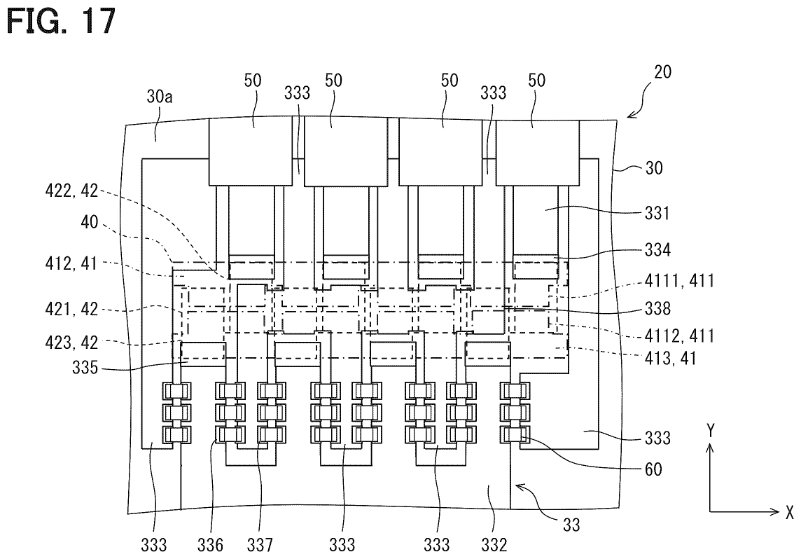

FIG. 17 is a plan view showing the electronic device according to the present embodiment. FIG. 17 corresponds to FIG. 3. In FIG. 17, the coupled inductor is shown in a see-through manner. Moreover, the resist is omitted. For convenience, the cover is omitted in FIG. 17. The outer periphery of the core is indicated by a single chain line, and the coil is indicated by a broken line.

The substrate 30 has the wiring 333 arranged on the surface layer adjacent to the first surface 30a, similar to the previous embodiment. The wiring 333 extends generally in the Y direction. The wiring 333 electrically connects the ground terminal of the capacitor 60 and a ground terminal (not shown) of the switching device 50. The substrate 30 has five wirings 333.

Of the five wirings 333, the wiring 333 disposed between the branched portions of the wiring 332 crosses the coupled inductor 40 in the Y direction. One of the wirings 333 is arranged to overlap a part of the body portion 421 of the coil 42A adjacent to the bottom wall 421b and a part of the body portion 421 of the coil 42B adjacent to the bottom wall 421a. The other wiring 333 is disposed to overlap a portion of the body portion 421 of the coil 42B adjacent to the bottom wall 421b and a portion of the body portion 421 of the coil 42C adjacent to the bottom wall 421a. The other wiring 333 is disposed to overlap a portion of the body portion 421 of the coil 42C adjacent to the bottom wall 421b and a portion of the body portion 421 of the coil 42D adjacent to the bottom wall 421a. The three wirings 333 that cross the coupled inductor 40 are connected to each other at position overlapping with the body portion 421 of the coil 42 in a plan view.

A portion of the three wirings 333 overlapping with the body portion 421 forms the non-joined conductor 338. Similar to the configuration shown in FIG. 3, the non-joined conductor 338 is disposed to overlap substantially the entire area of the body portion 421 of the coil 42B, 42C and to overlap a part of the body portion 421 of the coil 42A, 42D. Other configurations are the same as the configurations described in the preceding embodiment.

A portion of the wiring that provides a predetermined potential in the substrate 30 may be the non-joined conductor 338. In the electronic device 20, the wiring 333 corresponds to a wiring that provides a predetermined potential. Since the non-joined conductor 338 is fixed at a predetermined potential, the non-joined conductor 338 functions as an antenna, and radiation of the magnetic coupling component between the coil 42 and the non-joined conductor 338 can be suppressed. In other words, the radiation noise can be reduced. The same effect can be achieved in the case where a part of the ground wiring 339 is made into the non-joined conductor 338 as in the previous embodiment.

The coupled inductor 40 may be disposed between the switching device 50 and the capacitor 60 in the perpendicular direction that is perpendicular to both the thickness direction and the predetermined direction. In this arrangement, a portion of the ground wiring that electrically connects the capacitor 60 and the switching device 50 may be used as the non-joined conductor 338. In the electronic device 20, the Z direction corresponds to the thickness direction, and the X direction corresponds to the predetermined direction. The Y direction corresponds to the perpendicular direction. The wiring 333 corresponds to the ground wiring.

In this manner, the ground wiring is disposed directly below the coupled inductor 40, and a part of the ground wiring is used as the non-joined conductor 338. This shortens the return path from the capacitor 60 to the switching device 50, making it possible to suppress radiated noise. In FIG. 17, the capacitor 60 and the switching device 50 are electrically connected only by the wiring 333 arranged on the surface layer adjacent to the first surface 30a, thereby further shortening the return path and effectively reducing radiated noise.

### Modifications

The configuration in which a part of the ground wiring electrically connecting the capacitor 60 and the switching device 50 is the non-joined conductor 338 is not limited to the above example. An inner layer wiring disposed inside the insulating board 31 may be included as part of the ground wiring that electrically connects the capacitor 60 and the switching device 50. The inner layer wiring is connected to the surface layer wiring through a via conductor.

The plural wirings 333 are connected, but the present disclosure is not limited to this. The three wirings 333 crossing the coupled inductor 40 may be configured not to be connected. Of the multiple wirings 333 that cross the coupled inductor 40, some may be connected and the other may not be connected. When the wirings 333 are connected together, a return path can be shared.

The ground wiring electrically connecting the capacitor 60 and the switching device 50 is shown as the wiring for providing a predetermined potential, but the present disclosure is not limited to this. A ground wiring provided separately from the ground wiring electrically connecting the capacitor 60 and the switching device 50 may be used. The same effect can be achieved in the case where a part of the ground wiring 339 is made into the non-joined conductor 338 as in the previous embodiment. The predetermined potential is not limited to the ground potential. For example, the predetermined potential may be a power supply potential.

### Fifth Embodiment

The present embodiment is a modification based on the preceding embodiment and can incorporate the contents of the preceding embodiment. In the previous embodiment, a portion of the ground wiring is a non-joined conductor. Alternatively, a non-joined conductor may be provided continuous with the land.

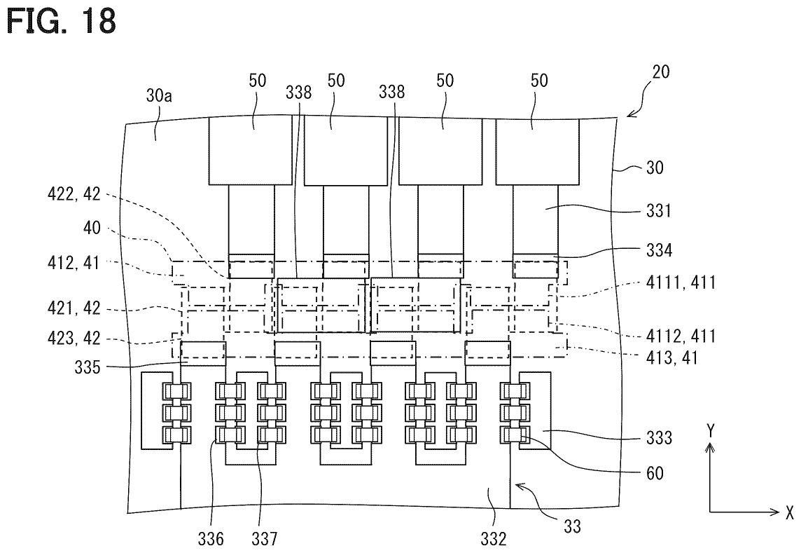

FIG. 18 is a plan view showing the electronic device according to the present embodiment. FIG. 18 corresponds to FIG. 3. In FIG. 18, the coupled inductor is shown in a see-through manner. Moreover, the resist is omitted. For convenience, the cover is omitted in FIG. 18. The outer periphery of the core is indicated by a single chain line, and the coil is indicated by a broken line.

In the electronic device 20, the non-joined conductor 338 is disposed on the surface layer adjacent to the first surface 30a and is connected to the land 334. The non-joined conductor 338 is covered with the resist 32. The substrate 30 has the non-joined conductor 338 disposed directly below the coil 42B, 42C, similar to the configuration shown in FIG. 15. The non-joined conductor 338 is not disposed directly below the coil 42A, 42D.

The non-joined conductor 338 is provided separately for the coils 42. The substrate 30 has two non-joined conductors 338. The non-joined conductor 338 located directly below the coil 42B is continuous with the land 334 to which the coil 42B is joined. The non-joined conductor 338 located directly below the coil 42C is connected to the land 334 to which the coil 42C is joined. The non-joined conductor 338 covers almost the entire area of the corresponding body portion 421. Other configurations are the same as the configurations described in the preceding embodiment.

The conductor 33 connected to the land 334 may be a non-joined conductor 338. This configuration also provides the same effect as the non-joined conductor 338 that is electrically isolated from the land 334, 335. For example, the area of the non-joined conductor 338 located directly below one coil 42 can be made smaller at directly below the end coil than at directly below the intermediate coil, thereby reducing the difference in inductance between the end coil and the intermediate coil.

### Modifications

A non-joined conductor 338 connected to the land 334 may be provided directly below the coil 42A, 42D.

The non-joined conductor 338 may be connected to either the land 334 or the land 335. For example, the conductor 33 connected to the land 335 may be a non-joined conductor 338.

### Other Embodiment

The disclosure in this description, the drawings, and the like is not limited to the exemplified embodiments. The disclosure includes embodiments and modifications by those skilled in the art based on the embodiments. For example, the disclosure is not limited to the combinations of components and/or elements shown in the embodiments. The disclosure may be implemented in various combinations. The disclosure may include additional portions that can be added to the embodiments. The disclosure includes those in which the components and/or elements of the embodiments are omitted. The disclosure includes the replacement or combination of components and/or elements between one embodiment and another embodiment. The disclosed technical scope is not limited to the description of the embodiments. The several technical scopes disclosed are indicated by the description of the claims, and should be further understood to include meanings equivalent to the description of the claims and all modifications within the scope.

The disclosure in the description, drawings and the like is not limited by the description of the claims. The disclosures in the description, the drawings, and the like encompass the technical ideas described in the claims, and further extend to a wider variety of technical ideas than those in the claims. Hence, various technical ideas can be extracted from the disclosure of the description, the drawings, and the like without being bound by the description of the claims.

When an element or layer is referred to as being “on,” “coupled,” “connected,” or “combined,” it may be directly on, coupled, connected, or combined to the other element or layer, or further, intervening elements or layers may be present. In contrast, when an element or a layer is described as “disposed directly above” or “directly connected”, an intervening element or an intervening layer is not present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. A reference to A and/or B includes A only, B only, or A and B. The description of A and/or B means at least one of A and B.

Spatially relative terms such as “inner,” “outer,” “back,” “below,” “low,” “above,” and “high” are utilized herein to facilitate description of one element or feature's relationship to another element(s) or feature(s) as illustrated. Spatial relative terms can be intended to include different orientations of a device in use or operation, in addition to the orientations depicted in the drawings. For example, when the device in the figure is flipped over, an element described as “below” or “directly below” another element or feature is directed “above” the other element or feature. Therefore, the term “below” can include both above and below. The device may be oriented in another direction (rotated 90 degrees or in any other direction) and the spatially relative terms used herein are interpreted accordingly.

What is claimed is:

1. An electronic device comprising:
a substrate having an insulating board and a conductor disposed on the insulating board; and
a coupled inductor having a core and a plurality of coils disposed on the core, the plurality of coils being arranged in a predetermined direction perpendicular to a thickness direction of the substrate and magnetically coupled to each other, wherein
the plurality of coils include end coils located at ends in the predetermined direction, and an intermediate coil located between the end coils,
each of the plurality of coils has a body portion wound around the core and a terminal portion connected to the body portion,
the conductor includes a land exposed from a surface of the substrate and joined to the terminal portion, and a non-joined conductor not joined to the coil, the non-joined conductor being provided at a position overlapping with the body portion in a plan view seen in a thickness direction, and
an area of the non-joined conductor located directly below one of the coils is smaller at directly below the end coil than at directly below the intermediate coil.

2. The electronic device according to claim 1, wherein the non-joined conductor is disposed directly below the end coil.

3. The electronic device according to claim 2, wherein the non-joined conductor is arranged to overlap the body portion of the end coil over an entire length in the predetermined direction.

4. The electronic device according to claim 3, wherein
the core has:
a plurality of core portions provided respectively for the coils and around which the body portion of the corresponding coil is wound;
a first end portion to which one ends of the plurality of core portions are connected; and
a second end portion to which the other ends of the plurality of core portions are connected,
the plurality of core portions are interposed between the first end portion and the second end portion in a perpendicular direction perpendicular to both the thickness direction and the predetermined direction,
the core portion is divided into a plurality of parts in the perpendicular direction to have a gap, and
the non-joined conductor corresponding to the end coil is disposed to overlap the gap in the plan view.

5. The electronic device according to claim 1, wherein the non-joined conductor is disposed directly below the intermediate coil and is not disposed directly below the end coil.

6. The electronic device according to claim 5, wherein the non-joined conductor is disposed directly below the intermediate coil and is not disposed directly below the end coil, in a layer of the substrate in which the land is arranged.

7. The electronic device according to claim 1, wherein the non-joined conductor is a part of a wiring that provides a predetermined potential in the substrate.

8. The electronic device according to claim 7, further comprising:
a switching device and a capacitor mounted on the substrate to define a multiphase power supply together with the coupled inductor, wherein
the coupled inductor is disposed between the switching device and the capacitor in a perpendicular direction perpendicular to both the thickness direction and the predetermined direction, and
the wiring is a ground wiring that electrically connects the capacitor and the switching device.
